(19) United States
(12) Patent Application Publication
(10) Pub. No.: US 2026/0344499 A1
(43) Pub. Date: Oct. 29, 2026

(54) PASSING SIGNALS THROUGH MICRO DEVICE SIDEWALLS

(71) Applicant: VueReal Inc., Waterloo (CA)

(72) Inventor: Gholamreza CHAJI, Kitchener (CA)

(73) Assignee: VueReal Inc., Waterloo (CA)

(21) Appl. No.: 19/737,438

(22) Filed: Jul. 10, 2026

Related U.S. Application Data
(63) Continuation of application No. 17/919,645, filed on May 11, 2021, now Pat. No. 12,708,019.
(60) Provisional application No. 63/022,671, filed on May 11, 2020.

(51) Int. Cl. H10W 72/90

(52) U.S. Cl. CPC H10W 72/944

(57) ABSTRACT

The present invention relates to structure and formation of side walls in micro devices. The structure allows access of one side of the micro device to another side through conductive layers and pads. In particular, the top and bottom sides of the micro devices are in direction of the current in the device and sidewalls are isolation surfaces surrounding the top and bottom sides of the device.

### CROSS-REFERENCE TO RELATED APPLICATIONS

The present application is a continuation of U.S. patent application Ser. No. 17/919,645 filed Oct. 18, 2022, which is a 371 of PCT/CA2021/050654 filed May 11, 2021 which claims benefit of U.S. application No. 63/022,671 filed May 11, 2020. The contents of each of these applications are incorporated herein by reference.

### BACKGROUND AND FIELD OF THE INVENTION

The present invention relates to formation of side walls in micro devices.

### SUMMARY

This invention relates to a micro device structure comprising, stacked layers comprising functional active, doped and blocking layers, a conductive layer deposited on a sidewall, the sidewall covered by a dielectric layer, the conductive layer coupling a contact from a top to a bottom of the micro device, and the conductive layer coupled to the device at least through one point. In an additional embodiment the conductive layer may cover at least part of the sidewall and may be extended over the dielectric layer at least in one area.

According to another embodiment, the invention discloses a method to pass a signal through a side wall of a micro device, the method comprising, having stacked layers comprising functional active, doped and blocking layers, depositing a first conductive layer on the sidewall, covering the sidewall covered by a dielectric layer, coupling a contact from a top to a bottom of the micro device though the first conductive layer; coupling the first conductive layer to the micro device at least through one point, and injecting the signal though the top and bottom of the micro device.

### BRIEF DESCRIPTION OF THE DRAWINGS

The foregoing and other advantages of the disclosure will become apparent upon reading the following detailed description and upon reference to the drawings.

FIG. 1. shows a side view of the micro device structure with a VIA and pads.

FIG. 2. shows a top view of the micro device structure.

FIG. 3. shows a bottom view of the micro device structure with pads.

FIG. 4. shows a side view of the micro device structure with a VIA and pads.

FIG. 5. shows a bottom view of the micro device structure.

FIG. 6. shows a top view of the micro device structure with pads.

While the present disclosure is susceptible to various modifications and alternative forms, specific embodiments or implementations have been shown by way of example in the drawings and will be described in detail herein. It should be understood, however, that the disclosure is not intended to be limited to the particular forms disclosed. Rather, the disclosure is to cover all modifications, equivalents, and alternatives falling within the spirit and scope of the invention as defined by the appended claims.

### DETAILED DESCRIPTION

In this description, the terms “device” and “micro device” are used interchangeably. However, it is clear to one skilled in the art that the embodiments described here are independent of the device size.

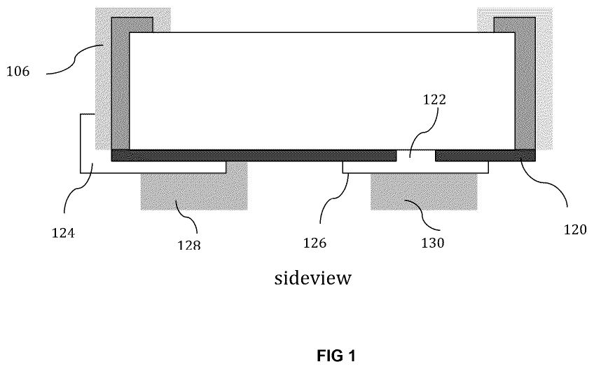

As shown in FIGS. 1, 2 and 3, a micro device structure 102 consists of stacked layers. The layers include active layers defining the functionality of the device, doped and blocking layers. The charges are injected into the device from the top and bottom. In one case, the contacts to the bottom and top need to be on either top or bottom. In this case, the contacts from one side need to move to the other side. The existing approach is to etch devices to create access to the doped or ohmic layer on the other side and deposit metal on the etched area and cover the doped or ohmic layer with a conductive layer. The challenge is that the etched area creates weak points in the device structure that can break under pressure. Furthermore, it reduces the device area.

In one embodiment there is a micro device structure comprising stacked layers comprising functional active, doped and blocking layers, a first conductive layer deposited on a sidewall; The device can have top side and bottom side and sidewalls. The top and bottom sides are in direction of the current in the device and sidewalls are isolation surfaces surrounding the top and bottom sides of the device. The top side is processed first and then the device is flipped and the bottom side is processed. There can be further processing on the top and bottom after forming the contacts or pads. The sidewall is covered by a dielectric layer; the first conductive layer coupling a contact from the bottom to the top surface of the micro device; and the first conductive layer coupled to the device at least through one point.

FIG. 1 shows an exemplary embodiment of connecting the top side of the device to a contact pad 128 on the bottom surface using conductive layer 106 deposited on the sidewall connected to the bottom and top contact. As shown in FIG. 1, after the bottom side of the device is separated from the substrate and the top side is fixed on a substrate, the conductive layer 106 is brought to the bottom side through another conductive layer 124. The conductive layer 124 is separated from the bottom side of the device by a dielectric layer 120. An opening or VIA 122 is formed in the dielectric 120 to provide access to the bottom side of the device. A conductive layer 126 is coupled to the bottom side through the VIA 122. Pads 128 and 130 are formed on top of the conductive layer 124 and 126. The conductive layer and pads can be the same as well.

The conductive layer 106 can be around the device. The conductive layer 124 can be around the device. There can be other dielectric layers on top of the conductive layers 106 or 124.

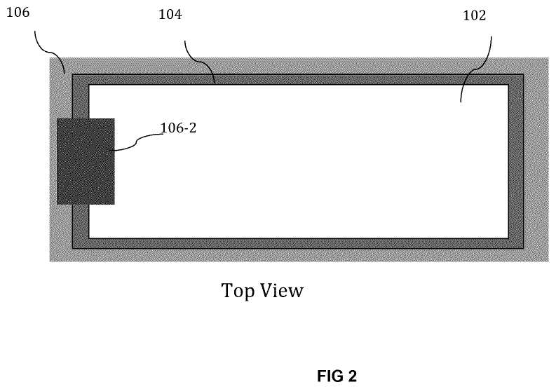

As shown in FIG. 2, the contact from the top or bottom is passed to the other side by depositing conductive layer 106 on the sidewall. The sidewall is covered by a dielectric layer. In one case, the top contact is coupled to the bottom side. Here the dielectric layer 104 on top of the device is opened and the conductive layer 106 is coupled to the device 102 at least through one point 106-2. The dielectric 104 opening can be smaller than the conductive point 106-2 covering the top surface. In another related case, the opening of the dielectric 104 can be larger than the conductive point 106-2.

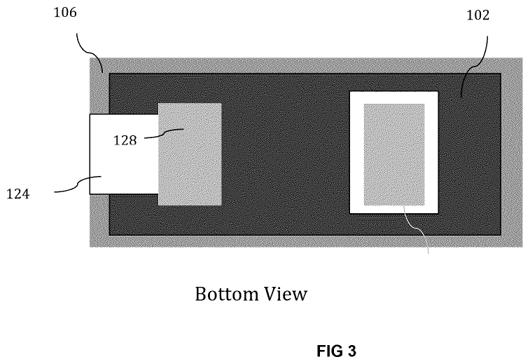

FIG. 3, shows a bottom view of the micro device structure with pads. Here, the conductive layer 106 is connected to a pad 128 on the bottom surface where the pad 128 is separated from the bottom surface by a dielectric layer. The connection 124 can be part of the pad 128 or a separate layer. The connection 124 covers at least part of the sidewall and the bottom surface. There can be another pad 130 connected to the bottom surface through an opening 122 in the dielectric layer 120 (demonstrated in FIG. 1).

Another related embodiment is a micro device structure comprising stacked layers comprising functional active, doped and blocking layers, a first conductive layer deposited on a sidewall; the sidewall covered by a dielectric layer; the first conductive layer coupling a contact from a top to a bottom surface of the micro device; and the first conductive layer coupled to the device at least through one point.

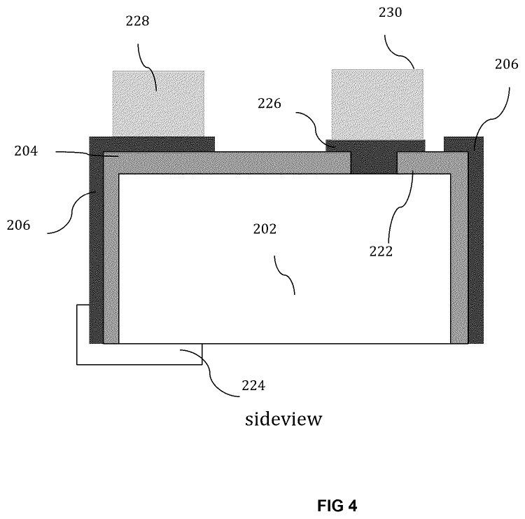

FIG. 4 shows an exemplary embodiment of connecting the bottom side of the device to a contact pad 128 on the top surface using conductive layer 106 deposited on the sidewall connected to the bottom and top contact. As shown in FIGS. 4, 5 and 6 a micro device structure 202 consists of stacked layers. The layers include active layers defining the functionality of the device, doped and blocking layers. The charges are injected into the device from the top and bottom. In one case, the contacts to the bottom and top need to be on either top or bottom. In this case, the contacts from one side need to move to the other side. The existing approach is to etch devices to create access to the doped or ohmic layer on the other side and deposit metal on the etched area and cover the doped or ohmic layer with a conductive layer. The challenge is that the etched area creates weak points in the device structure that can break under pressure. Furthermore, it reduces the device area. Here the conductive metal 206 is formed on the sidewall and part of the top side. A pad 228 is formed on the top side of the device where it is connected to the conductive layer 106 and the pad is separated from the device 202 by a dielectric layer 204. The dielectric layer 204 covers the sidewalls as well. The pad 228 or conductive layer 206 can be the same or share some layers. Another pad can be formed on the top surface where it is connected to the top of the device through an opening 222 in the dielectric layer 204. Another conductive layer 226 can form as part of the pad 230 or is the same as the pad 230. The conductive layer 226 can form at the same time as layer 206. The conductive layer 206 is connected to the bottom surface of the device 202 through a second conductive layer 224.

As shown in FIG. 4, pads 228 and 230 are formed on part of the conductive layers 206 and 226. The conductive layer and pads can be the same as well.

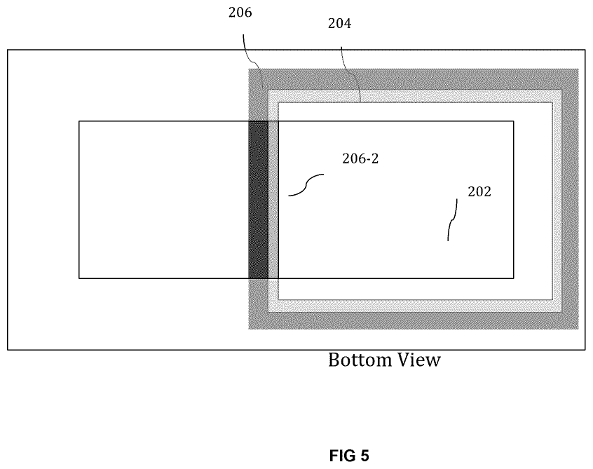

FIG. 5 shows a bottom view of the micro device structure. Here, the conductive layer 206 is around the device 202. A second conductive layer 224 is connecting the first conductive layer 206 to the bottom surface of the device 202. The bottom surface can have a dielectric layer and the layer 224 is connected to the bottom surface through an opening in the dielectric layer.

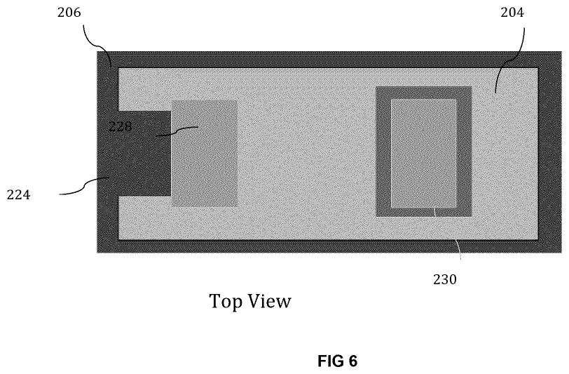

As shown in FIG. 6, the contact from the top or bottom is passed to the other side by depositing conductive layer 206 on the sidewall. The sidewall is covered by a dielectric layer. In one case, the bottom contact is coupled to the top side. Here the dielectric layer 204 on top of the device is opened and the conductive layer 226 coupled to the device 202 at least through one point 206-2. As shown in FIG. 6, The conductive layer 206 is deposited on at least part of the sidewall and extended over the dielectric layer 204 at least in one area.

As shown in FIG. 6, after the bottom side of the device is separated from the substrate and the top side is fixed on a substrate, the conductive layer 206 is brought to the bottom side through another conductive layer 224. The conductive layer 224 is coupled to the bottom side of the device.

The conductive layer 206 can be around the device. The conductive layer 224 can also be around the device. There can be other dielectric layers on top of the conductive layers 206 or 224.

### Method Embodiment

The invention disclose a method to pass a signal through a side wall of a micro device, the method comprising: having stacked layers comprising functional active, doped and blocking layers, depositing a first conductive layer on the sidewall, covering the sidewall covered by a dielectric layer, coupling a contact from a top to a bottom of the micro device though the first conductive layer, coupling the first conductive layer to the micro device at least through one point, and injecting the signal though the top and bottom of the micro device.

The foregoing description of one or more embodiments of the invention has been presented for the purposes of illustration and description. It is not intended to be exhaustive or to limit the invention to the precise form disclosed. Many modifications and variations are possible in light of the above teachings. It is intended that the scope of the invention be limited not by this detailed description, but rather by the claims appended hereto.

1. A microdevice structure includes: a stack of layers, including a functional active layer, a doped layer, and a blocking layer;
forming a first conductive metal layer on the sidewall and part of a top side; and
forming a first pad on the top side of the micro device where it is connected to the first conductive layer and the first pad is separated from the microdevice by a dielectric layer wherein the dielectric layer covers the sidewalls as well.

2. The structure of claim 1, wherein the first pad or first conductive metal layer are the same or share some layers.

3. The structure of claim 1, wherein a second pad is formed on the top surface where it is connected to the top of the microdevice through an opening in the dielectric layer.

4. The structure of claim 1, wherein a second conductive layer is formed as part of the second pad or is the same as the second pad.

5. The structure of claim 4, wherein the second conductive layer is at the same time as the first conductive layer wherein the first conductive layer is connected to the bottom surface of the microdevice through a second conductive layer.

6. The structure of claim 4, wherein the pads are formed on part of the conductive layers.

7. The structure of claim 4, wherein the first conductive layer is around the microdevice.

8. The structure of claim 7, wherein the second conductive layer is connecting the first conductive layer to a bottom surface of the microdevice.

9. The structure of claim 8, wherein the bottom surface can have a dielectric layer and the first conductive layer is connected to the bottom surface through an opening in the dielectric layer.

10. The structure of claim 9, wherein the contact from the top or bottom is passed to the other side by depositing first conductive layer on the sidewall wherein the sidewall is covered by a dielectric layer.

11. The structure of claim 10, wherein the bottom contact is coupled to the top side and the dielectric layer on top of the microdevice is opened and the second conductive layer is coupled to the microdevice at least through one point.

12. The structure of claim 10, wherein the first conductive layer is deposited on at least part of the sidewall and extended over the dielectric layer at least in one area.

13. The structure of claim 7, wherein the second conductive layer is also around the microdevice.
